(19) United States
(12) Patent Application Publication
(10) Pub. No.: US 2024/0178315 A1
(43) Pub. Date: May 30, 2024

(54) SEMICONDUCTOR DEVICE AND METHODS FOR FORMING THE SAME

(71) Applicant: Vanguard International Semiconductor Corporation, Hsinchu (TW)

(72) Inventors: Wen-Shan LEE, Hsinchu City (TW); Chung-Yeh LEE, Xinpu Township (TW); Fu-Hsin CHEN, Zhudong Township (TW)

(73) Assignee: Vanguard International Semiconductor Corporation, Hsinchu (TW)

(21) Appl. No.: 18/059,265

(22) Filed: Nov. 28, 2022

(51) Int. Cl. H01L 29/78; H01L 21/265; H01L 29/10; H01L 29/40; H01L 29/66

(52) U.S. Cl. CPC H01L 29/7806; H01L 21/26513; H01L 29/1095; H01L 29/407; H01L 29/66734; H01L 29/7813

(57) ABSTRACT

A semiconductor device includes a substrate having a first conductivity type, an epitaxial layer formed on the substrate, a well region extending from a top surface of the epitaxial layer into the epitaxial layer, a drift region formed in the epitaxial layer and in contact with the bottom surface of the well region, a gate structure and a conductive structure. The epitaxial layer has the first conductivity type, the well region has the second conductivity type, and the drift region has the first conductivity type. The gate structure that extends from the top surface of the epitaxial layer penetrates the well region and is in contact with the drift region. The conductive structure is formed in the drift region and disposed below the gate structure. A gate electrode of the gate structure is separated from the underlying conductive structure by the gate dielectric layer of the gate structure.

### BACKGROUND

### Technical Field

The disclosure relates to a semiconductor device and methods for forming the same, and it relates to a semiconductor device that includes a Schottky diode and methods for forming the same.

### Description of the Related Art

The integration density of different electronic components is being continuously improved in the semiconductor industry. Continuously decreasing the minimum size of components allows more and more components to be integrated into a given area. For example, trench gate metal-oxide-semiconductor field effect transistors, which are widely applied in power switch components, are designed to have a vertical structure to reduce the cell pitch and increase their functional density. In a trench gate metal-oxide-semiconductor field effect transistor (MOSFET), the back of the chip serves as a drain, while the sources and gates of various transistors are formed on the front of the chip. Accordingly, the flow of the driving current of a planar semiconductor device is in a horizontal direction, while the flow of the driving current of a trench gate semiconductor device is in a vertical direction, so that the trench gate semiconductor device can achieve a high-withstand voltage and a low on-resistance.

However, as the functional density of semiconductor devices continuously increases, the complexity of processing and manufacturing components of these semiconductor devices also increases. The trade-off performance between some electrical characteristics of a semiconductor device needs to be considered. Therefore, although existing semiconductor devices and methods for forming the same are generally adequate for their intended purposes, they have not been entirely satisfactory in all respects.

### SUMMARY

Some embodiments of the present disclosure provide semiconductor device. A semiconductor device includes a substrate, an epitaxial layer, a well region, a drift region, a gate structure and a conductive structure. The substrate has a first conductivity type. The epitaxial layer is formed on the substrate and has the first conductivity type. The well region is formed in the epitaxial layer and extends downward from the top surface of the epitaxial layer into the epitaxial layer. The well region has a second conductivity type. The drift region is formed in the epitaxial layer and in contact with the bottom surface of the well region. The drift region has the first conductivity type. The gate structure extends downward from the top surface of the epitaxial layer to penetrate the well region. The gate structure is in contact with the drift region. In addition, the conductive structure is formed in the drift region and positioned under the gate structure. A gate electrode of the gate structure is separated from the conductive structure by the gate dielectric layer of the gate structure.

Some embodiments of the present disclosure provide methods for forming a semiconductor device. A method for forming a semiconductor device includes providing a substrate having a first conductivity type and forming an epitaxial layer on the substrate. The epitaxial layer has the first conductivity type. The method includes implanting the top surface of the epitaxial layer to form a well region in the epitaxial layer. The well region has a second conductivity type. A drift region of the first conductivity type is formed under the well region and in contact with the bottom surface of the well region. The method further includes forming conductive structures in the drift region, and forming gate structures over the respective conductive structures. The gate structures extend downward from the top surface of the epitaxial layer to penetrate through the well region. The bottom portions of the gate structures are positioned in the drift region. Each of the gate structures includes a gate electrode and a gate dielectric layer that covers the gate electrode. The conductive structures are separated from the respective gate structures by the respective gate dielectric layers.

A detailed description is given in the following embodiments with reference to the accompanying drawings.

### BRIEF DESCRIPTION OF THE DRAWINGS

The embodiments of the disclosure can be more fully understood by reading the subsequent detailed description and examples with references made to the accompanying drawings. For clarity of illustration, various elements in the drawings may not be drawn to scale, wherein:

FIG. 1 to FIG. 18 illustrate cross-sectional views of intermediate stages of a method for forming a semiconductor device that includes gate structures and conductive structures, in accordance with some embodiments of the present disclosure.

FIG. 19 and FIG. 20 illustrate cross-sectional views of intermediate stages of a method for forming contact plugs and a source metal layer, in accordance with some embodiments of the present disclosure.

### DETAILED DESCRIPTION

The following description provides various embodiments, or examples, for implementing different features of the present disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numbers and/or letters in the various examples. This repetition is for the purpose of simplicity and clarity and does not in itself dictate a relationship between the various embodiments and/or configurations discussed.

In addition, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some embodiments are described below. Throughout the various views and illustrative embodiments, similar reference numbers are used to designate similar features/components. It should be understood that additional operations can be provided before, during, and after the method, and some of the operations can be replaced or eliminated for other embodiments of the method.

Embodiments provide semiconductor devices and methods for forming the same. In some embodiments, a semiconductor device that includes a Schottky diode can be formed to disable the function of a body diode, thereby decreasing the on-resistance and the power loss of the semiconductor device. Thus, the switching characteristics of the semiconductor device can be improved. In addition, a conductive structure that forms the Schottky diode of the embodiments is disposed under a gate structure, so the gate-drain capacitance (Cgd) can be reduced and no extra mesa area of the epitaxial layer to be occupied by the conductive structure. That is, there is no need to provide a lateral space on the surface of the epitaxial layer for forming a Schottky diode. Thus, the semiconductor devices provided in the embodiments can reduce the cell pitch between adjacent components (for example, the cell pitch between two adjacent gate structures) in the semiconductor devices, and the resistance of the channel region can be reduced. The embodiments can be applied to metal-oxide-semiconductor (MOS) devices, such as metal-oxide-semiconductor field effect transistors (MOSFETs). In some of the embodiments described below, a trench gate MOSFET is used to illustrate a semiconductor structure. However, the present disclosure is not limited thereto. Some embodiments of the present disclosure can be applied to other types of semiconductor structures.

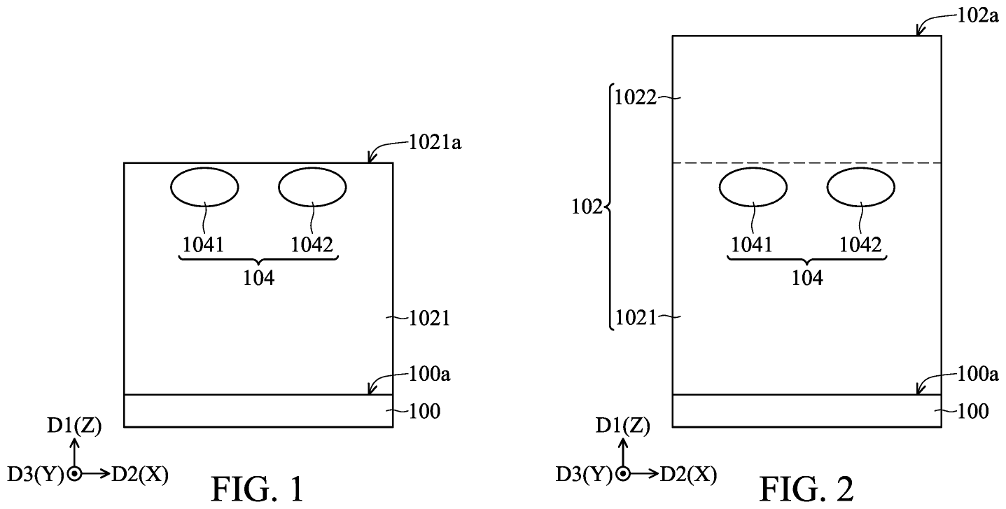

FIG. 1-FIG. 18 illustrate cross-sectional views of intermediate stages of a method for forming a semiconductor device that includes gate structures and conductive structures, in accordance with some embodiments of the present disclosure. The conductive structures are formed under the respective gate structures. In subsequent process, each of the conductive structures is electrically connected to a source electrode. The conductive structure and a drift region collectively form a Schottky diode that disables the function of a body diode, thereby decreasing the on-resistance and reducing the power loss of a semiconductor device.

Referring to FIG. 1A, a substrate 100 that has a first conductivity type is provided according to some embodiments. In some embodiments, the substrate 100 is a bulk semiconductor substrate, such as a semiconductor wafer. For example, the substrate 100 is a silicon wafer. In some embodiments, the substrate 100 includes silicon or another elemental semiconductor material. In some other embodiments, the substrate 100 includes another elemental semiconductor material such as germanium (Ge). In some embodiments, the substrate 100 includes compound semiconductor, such as silicon carbide, gallium nitride, gallium arsenide, indium arsenide, or indium phosphide. In some embodiments, the substrate 100 includes alloy semiconductor, such as silicon germanium, silicon germanium carbide, gallium arsenide phosphide, indium gallium phosphide, or another suitable alloy semiconductor. In some embodiments, the substrate 100 may also include a silicon-on-insulator (SOI) layer. The SOI substrate can be formed by using an oxygen implanted isolation (SIMOX) process, a wafer bonding process, another suitable method, or a combination thereof. In some embodiments, the substrate 100 includes different semiconductor materials, such as silicon, silicon germanium, silicon carbide and another suitable material. In this exemplified embodiment, the substrate 100 is, for example, a silicon wafer that is doped with dopants of the first conductivity type. In the application of a vertical trench-gate MOSFET, the substrate 100 that has the first conductivity type can act as a drain region of the semiconductor device. In addition, in this exemplified embodiment, the first conductivity type is n-type, but the present disclosure is not limited thereto. In some other embodiments, the first conductivity type can be p-type.

In some embodiments, an epitaxial growth process is performed to form an epitaxial layer 102 on the substrate 100. During the epitaxy process, the material is grown in the first direction D1 (for example, the Z direction) to form the epitaxy layer 102. In this exemplified embodiment, formation of the epitaxial layer 102 includes two stages, and several doping regions can be formed in the epitaxial layer 102 to serve as shielding regions for subsequently formed conductive structures.

Referring to FIG. 1, in some embodiments, an epitaxial growth process is performed on the top surface 100a of the substrate 100 to form a first epitaxial portion 1021 of the epitaxial layer 102. Next, an ion implantation process is performed in the first epitaxial portion 1021 to form doping regions 104 (such as the doping regions 1041 and 1042). In this exemplified embodiment, the doping region 1041 and the doping region 1042 are separated from each other by a distance in the second direction D2 (such as X direction). In addition, the doping region 1041 and the doping region 1042 may be (but not limited to) adjacent to the top surface 1021a of the first epitaxial portion 1021 of the epitaxial layer 102. Formation of doping regions 1041 and 1042 that have adequate depths in the epitaxial layer 102 can be controlled by adjusting the implant energy or using another suitable method.

In some embodiments, the substrate 100 and the first epitaxial portion 1021 of the epitaxial layer 102 have the same conductivity type, such as the first conductivity type. In this exemplified embodiment, the substrate 100 and the first epitaxial portion 1021 of the epitaxial layer 102 are n-type. In addition, the doping concentration of the first epitaxial portion 1021 of the epitaxial layer 102 is less than the doping concentration of the substrate 100.

In some embodiments, the epitaxial layer 102 and the doping regions 1041 and 1042 have different conductivity types. The doping region 1041 and the doping region 1042 have the second conductivity type. In this exemplified embodiment, the doping region 1041 and the doping region 1042 are p-type. In some embodiments, the dopants of doping region 1041 and doping region 1042 include aluminum (Al) or another suitable material. In some embodiments, the doping concentration of the doping regions 1041 and 1042 is in the range of about 1E16 atoms/cm³ to about 1E18 atoms/cm³.

Next, referring to FIG. 2, the epitaxial growth continues in the first direction D1 (for example, the Z direction) to grow a second epitaxial portion 1022 on the top surface 1021a of the first epitaxial portion 1021, in accordance with some embodiments of the present disclosure. The second epitaxial portion 1022 has the first conductivity type, such as n-type. In this exemplified embodiment, the first epitaxial portion 1021 and the second epitaxial portion 1022 collectively form an epitaxial layer 102.

In some embodiments, the aforementioned epitaxial growth process can be performed by using a metal organic chemical vapor deposition (MOCVD) process, a molecular beam epitaxy (MBE) process, a hydride vapor phase epitaxy (HVPE), a liquid phase epitaxy (LPE) process, a chloride vapor phase epitaxy (CI-VPE) process, another suitable process or a combination thereof to form the epitaxial layer 102. In the application of a semiconductor device, such as a vertical trench gate MOSFET, the epitaxial layer 102 that has the first conductivity type (such as n-type) can function as a drift region of the semiconductor device after the fabrication of transistor is completed.

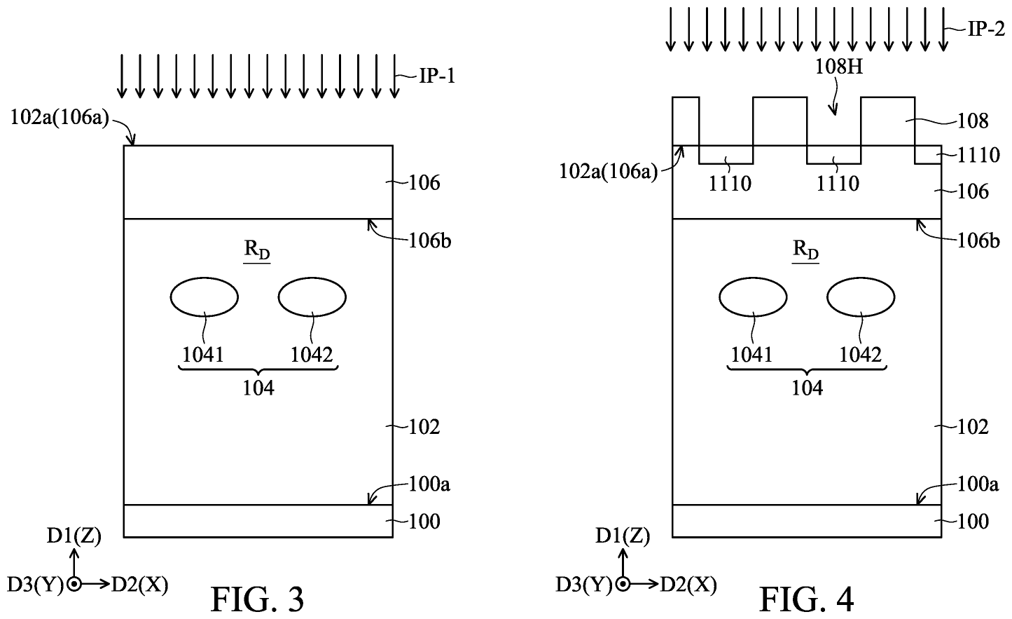

Referring to FIG. 3, in some embodiments, a well region 106 is formed in the epitaxial layer 102. The well region 106 and the epitaxial layer 102 have different conductivity types, such as the second conductivity type. The well region 106 is p-type, and can be referred to as a p-body region. The well region 106, the doping region 1041 and the doping region 1042 have the same conductivity type. In some embodiments, the doping concentration of the well region 106 is less than the doping concentration of the doping region 1041 and the doping region 1042. In some embodiments, the doping concentration of the well region 106 is in the range of about 1E16 atoms/cm³ to about 1E18 atoms/cm³. According to some embodiments, the well region 106 functions as a channel region of a semiconductor device.

In some embodiments, a well region 106 can be formed in the epitaxial layer 102 by using an ion implantation process IP-1. In one example, the well region 106 can be formed in the epitaxial layer 102 by doping from the top surface 102a of the epitaxial layer 102. Therefore, the well region 106 is doped downward from the top surface 102a of the epitaxial layer 102 to a certain depth of the epitaxial layer 102. The well region 106 is a doping region that extends in the first direction D1, the second direction D2 and the third direction D3. In addition, the epitaxial portion that is positioned under the well region 106 is a drift region R_{D}. The drift region Rp has the first conductivity type (such as n-type). In this exemplified embodiment, as shown in FIG. 3, the drift region R_{D} is in contact with the bottom surface 106b of the well region 106.

The above-mentioned well region 106 may be formed by a deposition process, a lithographic patterning process, an etching process and an implantation process, in accordance with some embodiments of the present disclosure. For example, an oxide hard mask material layer (not shown) may be deposited over the top surface 102a (FIG. 2) of the epitaxial layer 102. Then, a patterned photoresist (patterned PR) that has a pattern corresponding to the position of the well region 106 is formed on the oxide mask material layer, and the oxide hard mask material layer is etched through the patterned photoresist to form an oxide hard mask. Then, the patterned photoresist is removed, and the epitaxial layer 102 is doped through the formed oxide hard mask to form a well region 106 in the epitaxial layer 102. Then, the oxide hard mask can be removed.

Next, as shown in FIG. 4 to FIG. 6, several first heavily doped portions 1110 and several second heavily doped portions 1120 are alternately formed in the well region 106, in accordance with some embodiments of the present disclosure. Formations of the first heavily doped portions 1110 and the second heavily doped portions 1120 are similar to the steps for forming the well region 106.

Referring to FIG. 4, in some embodiments, several first heavily doped portions 1110 are formed in the well region 106 by using suitable implantation process. For example, the first heavily doped portions 1110 can be formed by doping from the top surface 106a of the well region 106 (i.e., the top surface 102a of the epitaxial layer 102). Those first heavily doped portions 1110 are separated from each other by a distance (such as in the second direction D2). In one exemplified embodiment, those first heavily doped portions 1110 and the well region 106 have the same conductivity type, such as the second conductivity type. In this embodiment, the first heavily doped portions 1110 and the well region 106 are p-type. In some embodiments, the doping concentration of the first heavily doped portions 1110 is greater than the doping concentration of the well region 106. In some embodiments, the doping concentration of the first heavily doped portions 1110 is in the range of about 1E18 atoms/cm³ to about 1E21 atoms/cm³.

According to some embodiments, the above-mentioned first heavily doped portions 1110 may be formed by using a deposition process, a lithographic patterning process, an etching process, and an implantation process. In one exemplified embodiment, a hard mask material layer (not shown), such as an oxide hard mask material layer, may be deposited over the top surface 106a of the well region 106, and then a patterned photoresist (not shown) is formed on the hard mask material layer. Next, the hard mask material layer is etched by using the patterned photoresist as a mask to form a patterned hard mask (such as an oxide hard mask) 108. The patterned hard mask 108 has several openings 108H that correspond to the positions of the first heavily doped portions 1110 to be formed subsequently. Next, as shown in FIG. 4, the patterned photoresist is removed, and the patterned hard mask 108 remains on the well region 106. An ion implantation process IP-2 is performed on the well region 106 through the patterned hard mask 108 to form the first heavily doped portions 1110 in the well region 106. Therefore, the first heavily doped portions 1110 extend downward from the top surface 106a of the well region 106 (i.e., the top surface 102a of the epitaxial layer 102) into the well region 106. Then, the patterned hard mask 108 can be removed.

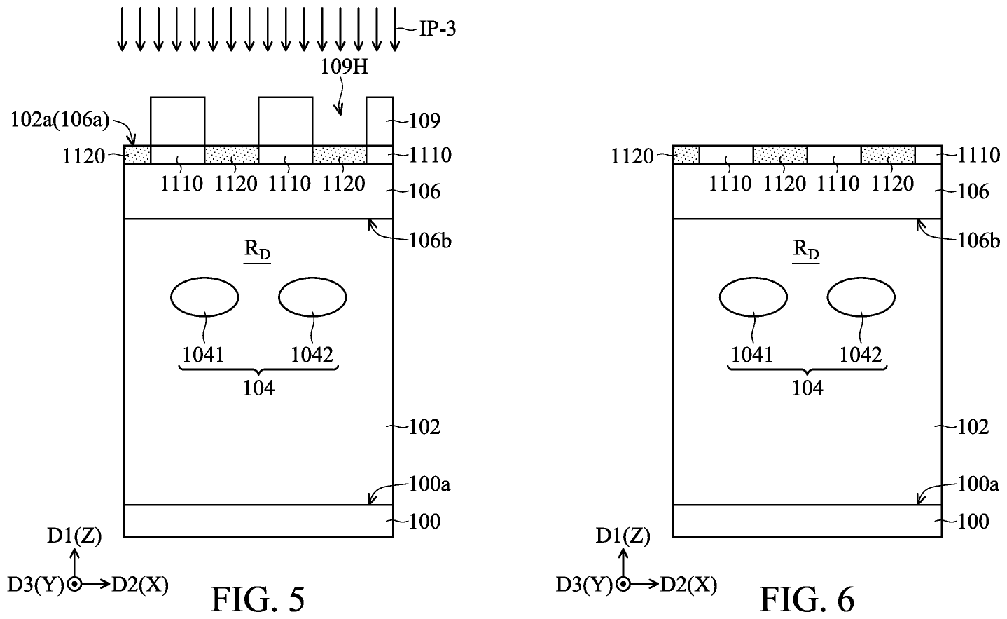

Referring to FIG. 5, in some embodiments, several second heavily doped portions 1120 are formed in the well region 106 by using suitable implantation process. For example, the second heavily doped portions 1120 can be formed by doping from the top surface 106a of the well region 106 (i.e., the top surface 102a of the epitaxial layer 102). Those second heavily doped portions 1120 are separated from each other by a distance (such as in the second direction D2). In one exemplified embodiment, those second heavily doped portions 1120 and the epitaxial layer 102 have the same conductivity type, such as the first conductivity type. In this embodiment, the second heavily doped portions 1120 are n-type. In some embodiments, the doping concentration of the second heavily doped portions 1120 is greater than the doping concentration of the epitaxial layer 102. In some embodiments, the doping concentration of the second heavily doped portions 1120 is in the range of about 1E18 atoms/cm³ to about 1E21 atoms/cm³.

According to some embodiments, the above-mentioned second heavily doped portions 1120 may be formed by using a deposition process, a lithographic patterning process, an etching process, and an implantation process. In one exemplified embodiment, another hard mask material layer (not shown)(such as an oxide hard mask material layer) may be deposited over the top surface 106a of the well region 106, and then another patterned photoresist (not shown) is formed on the hard mask material layer. Next, the hard mask material layer is etched by using the patterned photoresist as a mask to form a patterned hard mask (such as an oxide hard mask) 109. The patterned hard mask 109 has several openings 109H that correspond to the positions of the second heavily doped portions 1120 to be formed subsequently. Next, the patterned photoresist is removed, and the patterned hard mask 109 remains on the well region 106, as shown in FIG. 5. An ion implantation process IP-3 is performed on the well region 106 through the patterned hard mask 109 to form the second heavily doped portions 1120 in the well region 106. Therefore, the second heavily doped portions 1120 extend downward from the top surface 106a of the well region 106 (i.e., the top surface 102a of the epitaxial layer 102) into the well region 106. Then, the patterned hard mask 109 can be removed.

Referring to FIG. 6, after the patterned hard mask 109 (FIG. 5) is removed, a high temperature activation process may be performed to activate dopants in the first heavily doped portions 1110 and the second heavily doped portions 1120, in accordance with some embodiments of the present disclosure. In this exemplified embodiment, as shown in FIG. 6, the first heavily doped portions 1110 and the second heavily doped portions 1120 are alternately arranged on the top surface 106a of the well region 106 (i.e., the top surface 102a of the epitaxial layer 102).

In addition, in some embodiments that the epitaxial layer 102 includes silicon carbide (SiC), the top surface 102a of the epitaxial layer 102 can be covered with a graphite layer (which can be referred to as a graphite cap)(not shown) before the high temperature activation process is performed. The graphite layer protects the SiC surface from out-diffusion of Si during the high temperature activation process. After the high temperature activation process is completed, the graphite layer is removed.

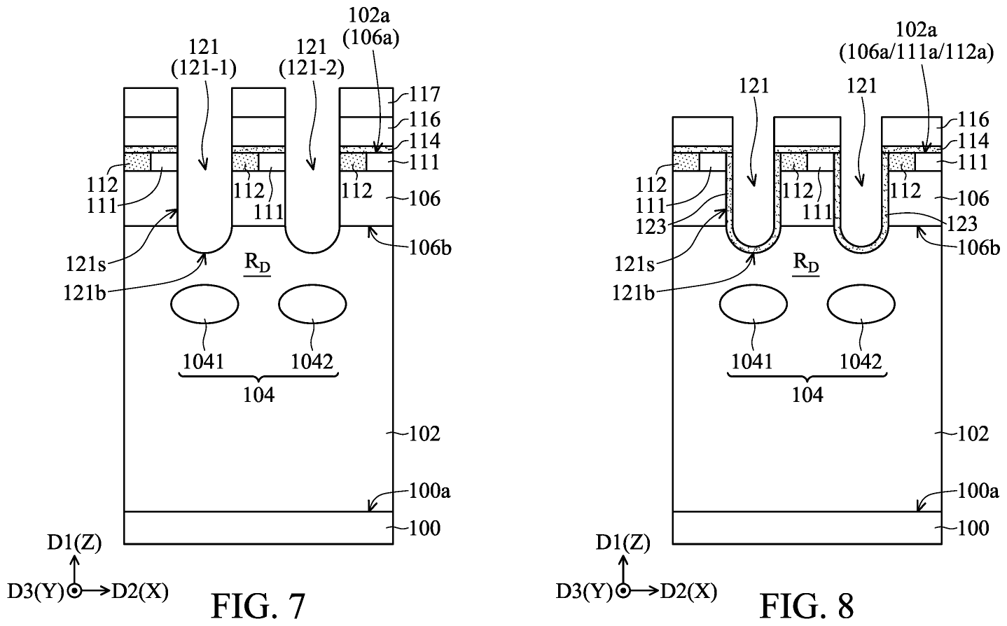

Next, referring to FIG. 7, parts of the first heavily doped portions 1110, parts of the second heavily doped portions 1120, parts of the well region 106 and parts of the epitaxial layer 102 are removed, so as to form several first trenches 121, in accordance with some embodiments of the present disclosure. In some embodiments, the positions of first trenches 121 correspond to the positions of shielding regions 104′ that can be used as the shielding regions for subsequently formed conductive structures. The first trenches 121 include the first trenches 121-1 and 121-2. The positions of the first trench 121-1 and the first trench 121-2 correspond to the underlying doping region 1041 and the doping region 1042 having the second conductivity type (for example, p-type), respectively.

In some embodiments, as shown in FIG. 7, the first trenches 121, such as two first trenches 121-1 and 121-2 that are separated from each other, extend from the top surface 102a of the epitaxial layer 102 and penetrate through the well region 106 to reach the drift region R_{D}. In this exemplified embodiment, the lower portion of the lateral surface 121s of the first trench 121 and the bottom surface 121b of the first trench 121 expose the drift region R_{D}.

In addition, after the first trenches 121 are formed, the remaining parts of the first heavily doped portions 1110 are referred to as the first heavily doped regions 111. The first heavily doped regions 111 provide good ohmic contact between the well region 106 and the contact plugs 172 (FIG. 20) that are subsequently formed above the first heavily doped regions 111. The remaining parts of the second heavily doped portions 1120 are referred to as the second heavily doped regions 112, which serve as the source regions of the semiconductor device. The first heavily doped regions 111 have the second conductivity type, such as p-type. The second heavily doped regions 112 have the first conductivity type, such as n-type. In some embodiments, as shown in FIG. 7, the opposite sides of each first trench 121 are in contact with respective one of the first heavily doped regions 111 and one of the second heavily doped regions 112. An upper portion of the lateral surface 121s of the first trench 121 exposes the well region 106, one of the first heavily doped regions 111 and one of the second heavily doped regions 112.

According to some embodiments, the above-mentioned first trenches 121 may be formed by one or more deposition processes, one or more lithographic patterning processes, and one or more etching processes. In one exemplified embodiment, a pad oxide material layer (not shown) and a nitride hard mask material layer (not shown) may be deposited on the first heavily doped portions 1110 and the second heavily doped portions 1120, and a patterned photoresist layer 117 is formed on the nitride hard mask material layer. The pad oxide material layer can avoid excessive stress that is caused by the direct contact between the nitride hard mask material layer and the epitaxial layer (including silicon carbide, for example). Then, the nitride hard mask material layer, the pad oxide material layer and the heavily doped portions (including parts of the first heavily doped portions 1110, parts of the second heavily doped portions 1120) under the pad oxide material layer, and the well region 106 are sequentially etched to form the above-mentioned first trenches 121, by using the patterned photoresist layer 117 as a mask. Parts of the drift region R_{D} are also removed during formation of the first trenches 121. In some embodiments, the etching process includes a dry etching process, a wet etching process, a plasma etching process, a reactive ion etching process, another suitable process, or a combination of the foregoing processes. In addition, it should be noted that dimensions, shapes and positions of the first trenches 121 are provided for illustrative purposes, and the embodiments of the present invention are not limited thereto.

In some embodiments, after the first trenches 121 are formed, the patterned photoresist layer 117 is removed. A pad oxide layer 114 and a nitride hard mask 116 are remained on the first heavily doped regions 111 and the second heavily doped regions 112 after the patterned photoresist layer 117 is removed. Then, a cleaning process is performed to clean the structure.

Next, referring to FIG. 8, in some embodiments, an insulating layer 123 is formed on the lateral surfaces 121s and the bottom surfaces 121b of the first trenches 121. In some embodiments, the insulating layer 123 includes silicon oxide, or another suitable semiconductor oxide material, or a combination of the foregoing materials. In some examples, the insulating layer 123 can be conformably formed on the lateral surfaces 121s and the bottom surfaces 121b of the first trenches 121 by using an oxidation process. In some embodiments, the oxidation process may include a thermal oxidation process, a radical oxidation process, or another suitable process. In one example where the epitaxial layer 102 includes silicon carbide (SiC), silicon carbide the lateral surfaces 121s and the bottom surfaces 121b of the first trenches 121 can be oxidized to form a silicon oxide layer by using a high-temperature process (for example, using a high-temperature furnace), and the silicon oxide layer acts as the insulating layer 123.

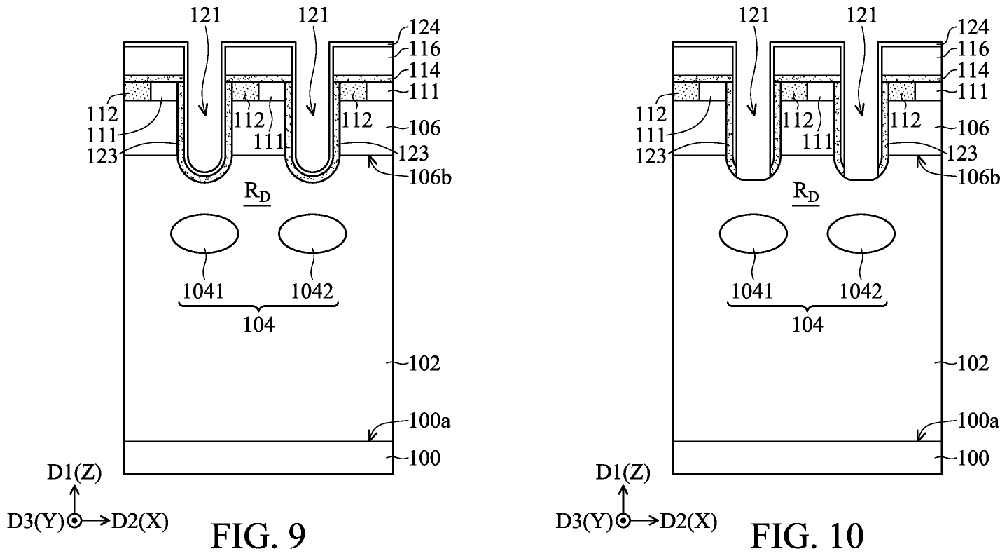

Next, the fabrication of conductive structures 130 (as shown in FIG. 14) that are formed under the first trenches 121 is performed. Some intermediate stages for fabricating the conductive structures 130 are, for example (but not limited to), illustrated in FIG. 9 to FIG. 14, in accordance with some embodiments of the present disclosure.

Referring to FIG. 9, in some embodiments, a spacer layer 124 is formed in the first trenches 121. In some embodiments, the spacer layer 124 is conformably formed on the top surfaces and lateral surfaces of the nitride hard mask 116, the lateral surfaces of the pad oxide layer 114 and the insulating layer 123 in the first trenches 121 by a deposition process. In this exemplified embodiment, the spacer layer 124 covers all of the exposed surfaces of the insulating layer 123 in the first trenches 121. The spacer layer 124 also reduces the width of each of the first trenches 121 in the second direction D2 (such as X direction).

In some embodiments, the spacer layer 124 includes silicon nitride, silicon oxynitride, another suitable spacer material, or a combination of the foregoing materials. The material of the spacer layer 124 may be the same as the material of the nitride hard mask 116. The material of the spacer layer 124 may be different from the material of the nitride hard mask 116. In this exemplified embodiment, the spacer layer 124 and the nitride hard mask 116 include silicon nitride. In addition, the deposition process for forming the spacer layer 124 is, for example, a conformal deposition process, and may include a physical vapor deposition (PVD) process, a chemical vapor deposition (CVD) process, an atomic layer deposition (ALD) process, another suitable deposition process, or a combination of the aforementioned processes.

Referring to FIG. 10, a portion of the spacer layer 124 and a portion of the insulating layer 123 are removed by using an etching process to expose the epitaxial material of the drift region R_{D}, in accordance with some embodiments of the present disclosure. The etching process is an anisotropic etching process, and the first trenches 121 continue to extend toward the substrate 100. For example, the first trenches 121 extend further in the first direction D1 (such as Z direction). Specifically, for the spacer layer 124 (i.e. the to-be-etched material layer), the aforementioned etching process etches the material in the first direction D1, but substantially does not etch the material in the second direction D2.

In some embodiments, the aforementioned etching process includes a blanket etching process that is performed without using any photoresist. In this exemplified embodiment, the blanket etching process is performed along the sidewalls 124s of the spacer layer 124 in the first trenches 121 to anisotropically etch the bottom of the spacer layer 124 and the bottom of the insulating layer 123. A portion of the spacer layer 124 and a portion of the insulating layer 123 can be removed until the epitaxial layer 102 is exposed. That is, the epitaxial layer 102 is an etch stop layer for this blanket etching process. In this exemplified embodiment, the aforementioned blanket etching process is a dry etching process.

In addition, in this exemplified embodiment, the nitride hard mask 116 remained on the pad oxide layer 114 can prevent the aforementioned blanket etching process (i.e. an anisotropic etching process performed in the first direction D1) from damaging the pad oxide layer 114 and the underlying first heavily doped regions 111 and the second heavily doped regions 112.

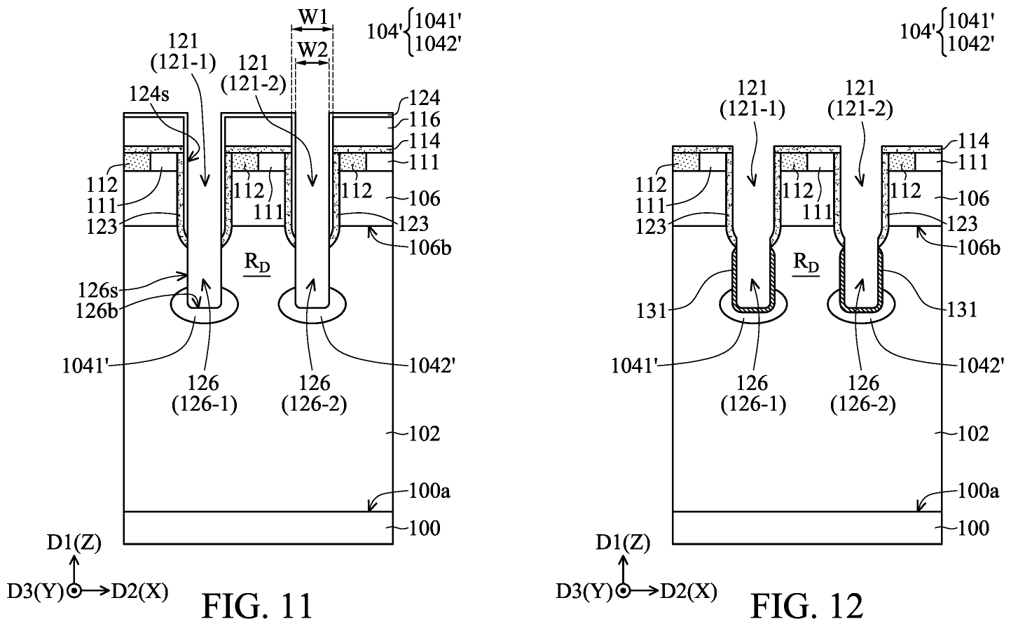

Referring to FIG. 11, portions of the epitaxial layer 102 (the epitaxial material layer of the drift region R_{D}), portions of the doping region 1041 and portions of the doping region 1042 are removed from the bottom surfaces of the extended first trenches 121 to form several second trenches 126, in accordance with some embodiments of the present disclosure. The second trenches 126 communicate with the respective first trenches 121. The bottom surfaces 126b of the second trenches 126 stop in the doping region 1041 and the doping region 1042. In addition, in some embodiments, the lateral surfaces 126s of the second trenches 126 are self-aligned with the sidewalls 124s of the spacer layer 124 in the respective first trenches 121.

Specifically, in this exemplified embodiment, the second trench 126-1 is continuous with the first trench 121-1 and extends further in the epitaxial layer 102. A portion of the doping region 1041 is removed by the second trench 126-1. The bottom surface 126b of the second trench 126-1 stops in the doping region 1041. After the second trench 126-1 is formed, the remaining portion of the doping region 1041 can be used as a shielding region 1041′ for shielding the subsequently formed conductive structure 130 (FIG. 14). Similarly, the second trench 126-2 is continuous with the first trench 121-2 and extends in the epitaxial layer 102. A portion of the doping region 1042 is removed by the second trench 126-2, and the bottom surface 126b of the second trench 126-2 stops in doping region 1042. After the second trench 126-2 is formed, the remaining portion of the doping region 1042 can be used as a shielding region 1042′ for shielding the subsequently formed conductive structure 130 (FIG. 14).

In some embodiments, the second trenches 126, such as the second trenches 126-1 and 126-2 that are separated from each other as shown in FIG. 11, connect the first trenches 121 and extend in the epitaxial layer 102 to reach the shielding region 1041′ and the shielding region 1042′. In other words, in this exemplified embodiment, the upper portion of the lateral surface 126s of the second trench 126-1 exposes the drift region R_{D}, and the lower portion of the lateral surface 126s and the bottom surface 126b of the second trench 126-1 expose the shielding region 1041′. Similarly, the upper portion of the lateral surface 126s of the second trench 126-2 exposes the drift region R_{D}, and the lower portion of the lateral surface 126s and the bottom surface 126b of the second trench 126-2 expose the shielding region 1042′.

In some embodiments, the portions of the epitaxial layer 102 in the drift region R_{D}, the portion of the doping region 1041, and the portion of the doping region 1042 can be removed by a suitable etching process to form the second trenches 126. The aforementioned etching process may include a dry etching process, a wet etching process, a plasma etching process, a reactive ion etching process, another suitable process, or a combination of the aforementioned processes. In addition, it should be noted that dimensions, shapes and positions of the second trenches 126 are provided for illustrative purposes, and the embodiments of the present invention are not limited thereto.

After the second trenches 126 are formed, the spacer layer 124 and the nitride hard mask 116 are removed, thereby exposing the pad oxide layer 114 (that is above the first heavily doped regions 111 and the second heavily doped regions 112) and the remaining portions of the insulating layer 123 positioned in the first trenches 121. In some embodiments, the spacer layer 124 and the nitride hard mask 116 can be removed by, for example, an isotropic etch process such as a wet etching process (for example, an acid etch), or another acceptable process.

In addition, after the spacer layer 124 and the nitride hard mask 116 are removed, the width W1 (for example, the width in the second direction D2) of each of the first trenches 121 is greater than the width W2 (for example, the width in the second direction D2) of each of the second trenches 126, in accordance with some embodiments of the present disclosure.

According to the aforementioned descriptions, the second trenches 126 are formed under the respective first trenches 121. In subsequent processes, the second trenches 126 can be filled with suitable conductive materials to form the conductive structures 130, in accordance with some embodiments of the present disclosure.

Referring to FIG. 12, a metal silicide liner 131 is formed on the lateral surface 126s and the bottom surface 126b of each of the second trenches 126, in accordance with some embodiments of the present disclosure. In some embodiments, the metal silicide liner 131 in each of the second trenches 126 is in direct contact with the epitaxial layer 102 (such as in direct contact with the epitaxial material of the drift region R_{D}) and the shielding region (in direct contact with such as the shielding region 1041′ or the shielding region 1042′).

In an example where the epitaxial layer 102 includes silicon carbide (SiC), the metal silicide liner 131 is, for example, a metal silicide that is formed after a metal material reacts with silicon carbide. In some embodiments, the metal silicide liner 131 includes titanium silicide (TiSi₂), nickel silicide (NiSi), platinum silicide (PtSi), or another suitable metal silicide material.

In some embodiments, the epitaxial layer 102 includes silicon carbide (SiC). A metal material layer that can react with silicon carbide is deposited over the entire surface of the epitaxial layer 102. The metal material layer, for example, is conformably deposited on the pad oxide layer 114, the remaining portions of the insulating layer 123 in the first trenches 121, and the lateral surfaces 126s and the bottom surfaces 126b of the second trenches 126. In some embodiments, the metal material can be deposited by using a chemical vapor deposition (CVD) process, an atomic layer deposition (ALD) process, a physical vapor deposition (PVD) process, another suitable process, or a combination of the foregoing processes. Then the portions of the metal material layer that are deposited in the second trenches 126 can react with silicon carbide (SiC) by using a rapid thermal processing (RTP) to form metal silicide, such as titanium silicide, nickel silicide, platinum silicide or another metal silicide. However, the portions of the metal material layer that are deposited on the pad oxide layer 114 and the remaining portions of the insulating layer (for example, including oxide) 123 do not react with the pad oxide layer 114 and the insulating layer 123 and remains a metal material layer. After the reaction is completed, the unreacted portions of the metal material layer are removed (for example, by using a suitable acid etchant) to expose the pad oxide layer 114 and the remaining portions of the insulating layer 123 in the first trenches 121. Therefore, a metal silicide liner 131 is formed on the lateral surface 126s and the bottom surface 126b of each of the second trenches 126, as shown in FIG. 12. In this exemplified embodiments, a topmost portion of the metal silicide liner 131 in each of the second trenches 126 is adjacent to, or in direct contact with a bottommost portion of the remaining portion of the insulating layer 123 in each of the first trenches 121.

After the metal silicide liners 131 are formed in respective second trenches 126, a conductive portion 132 is formed in each of the second trenches 126. A conductive structure 130 that includes the metal silicide liners 131 and the conductive portion 132 in each of the second trenches 126 can be formed. Some exemplified forming methods are described below.

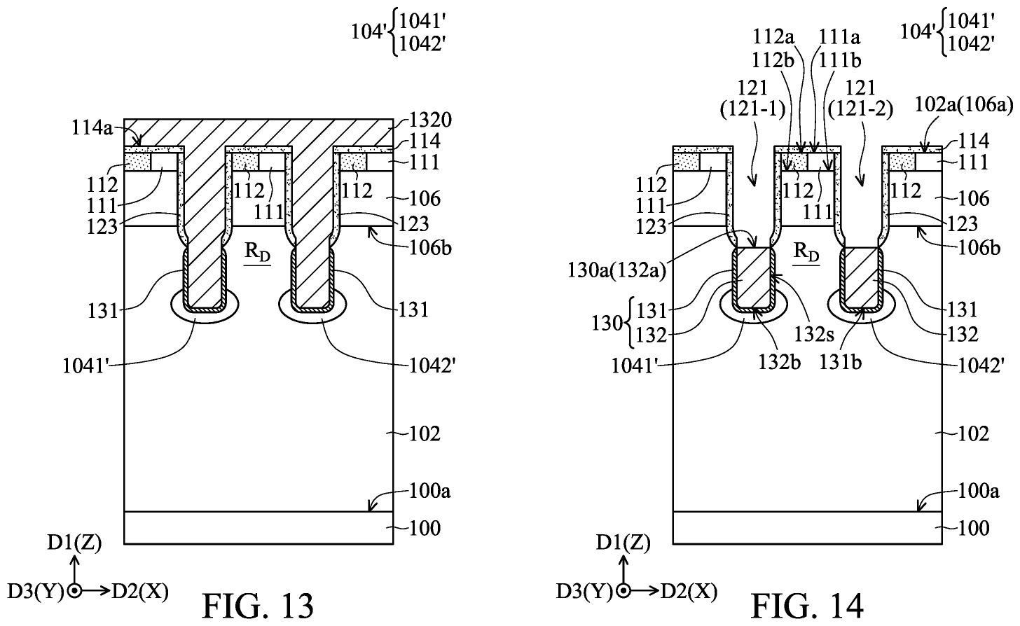

Referring to FIG. 13, a first conductive material 1320 is deposited on the structure shown in FIG. 12, in accordance with some embodiments of the present disclosure. The first conductive material 1320 fills the second trenches 126 and the first trenches 121. The first conductive material 1320 is excessively deposited over the top surface 114a of the pad oxide layer 114, as shown in FIG. 13.

In some embodiments, the first conductive material 1320 can be formed of metal, alloy, polysilicon, another suitable conductive material, or a combination of the aforementioned materials. In some embodiments, the first conductive material 1320 can be a single-layer structure or a multilayer structure. In this exemplified embodiment, the first conductive material 1320 includes a single layer of polysilicon. The portions of the first conductive material 1320 in the second trenches 126 are separated from the epitaxial layer 102 by the metal silicide liners 131.

In some exemplified embodiments, the aforementioned deposition process for the deposition of the first conductive material 1320 includes a physical vapor deposition (PVD) process, a chemical vapor deposition (CVD) process, another suitable process, or a combination of the foregoing processes.

Next, referring to FIG. 14, a portion of the first conductive material 1320 is removed, so that the remaining portion of the first conductive material 1320 fills the second trenches 126 to form the conductive portions 132, in accordance with some embodiments of the present disclosure.

In some embodiments, the metal silicide liner 131 and the conductive portion 132 in each of the second trenches 126 collectively form a conductive structure 130. In this exemplified embodiment, the metal silicide liner 131 covers the sidewall 132s and the bottom surface 132b of the conductive portion 132 in the second trench 126, as shown in FIG. 14.

In some embodiments, the step of removing a portion of the first conductive material 1320 may (but not limited to) include forming a patterned photoresist on the first conductive material 1320, and etching the conductive material 1320 for removing the portion of the first conductive material 1320. The remaining portion of the first conductive material 1320 in each of the second trenches 126 has a specific depth in the epitaxial layer 102. After the portion of the first conductive material 1320 is removed, the conductive portions 132 are formed in the respective second trenches 126, as shown in FIG. 14.

In some other embodiments, the aforementioned step of removing part of the first conductive material 1320 may (but not limited to) include removal of the excess portion of the first conductive material 1320 by a planarization process to expose the pad oxide layer 114. For example, the portion of the first conductive material 1320 above the pad oxide layer 114 is removed to expose the pad oxide layer 114. The aforementioned planarization process is, for example, a chemical mechanical polishing (CMP) process, a mechanical polishing process, an etching process, another suitable process, or a combination of the aforementioned processes. Then, the portions of the first conductive material 1320 in the first trenches 121 are etched back, so that the first conductive material 1320 is recessed to a certain depth to form the conductive portions 132 in the second trenches 126, as shown in FIG. 14.

According to some embodiments, the metal silicide liner 131 of the conductive structure 130 in each of the second trenches 126 can serve as a Schottky barrier at a junction between the conductive portion 132 and the drift region R_{D} that has the second conductivity type (for example, n-type). In addition, each of the conductive structures 130 is electrically connected to a source electrode (such as the metal layer 182 in FIG. 20) in subsequent process, so that the conductive structure 130 and the drift region R_{D} form a Schottky diode. The interface between the well region 106 and the drift region R_{D} of different conductivity types inherently includes a parasitic diode (i.e. an intrinsic diode), which is known as a body diode. The Schottky diode of the embodiment is connected in parallel with the body diode. Since the energy barrier of the Schottky diode is lower than the energy barrier of the body diode (that is, the Schottky diode has a lower on-resistance (Von)), charge carriers will pass through the Schottky diode instead of the body diode when a semiconductor device is operated. Therefore, after the conductive structures 130 of the embodiment are electrically connected to a source electrode in subsequent process, the aforementioned Schottky diode as formed can disable the function of the body diode, thereby decreasing the on-resistance and reducing the power loss of the semiconductor device.

In addition, the conductive structures 130 are positioned in the lower position of the drift region R_{D} instead of adjacent to the top surface 102a of the epitaxial layer 102, in accordance with some embodiments of the present disclosure. Therefore, the conductive structures 130 provided in the embodiments does not need to occupy additional mesa areas of the epitaxial layer 102, so the cell pitch between adjacent components in the semiconductor device can be reduced. Consequently, the resistance of the channel region in the semiconductor device can be decreased.

In some embodiments, as shown in FIG. 14, the top surfaces 130a of the conductive structures 130 (i.e., the top surfaces 132a of the conductive portions 132) are lower than the top surface of the epitaxial layer 102 (i.e., the top surface 106a of the well region 106).

In some embodiments, as shown in FIG. 14, the top surfaces 130a of the conductive structures 130 (i.e., the top surfaces 132a of the conductive portions 132) are lower than the top surfaces 111a of the first heavily doped regions 111. In addition, the top surfaces 130a of the conductive structures 130 are lower than the bottom surfaces 111b of the first heavily doped regions 111. Similarly, the top surfaces 130a of the conductive structures 130 (i.e., the top surfaces 132a of the conductive portions 132) are lower than the top surfaces 112a of the second heavily doped regions 112. In addition, the top surfaces 130a of the conductive structures 130 are lower than the bottom surfaces 112b of the second heavily doped regions 112.

In some embodiments, as shown in FIG. 14, the top surfaces 130a of the conductive structures 130 are lower than the bottom surface 106b of the well region 106. Therefore, the conductive structures 130 are buried in the drift region R_{D}, and the top surfaces 130a of the conductive structures 130 are separated from the bottom surface 106b of the well region 106 by a distance in the first direction D1 (such as Z direction), in accordance with some embodiments of the present disclosure.

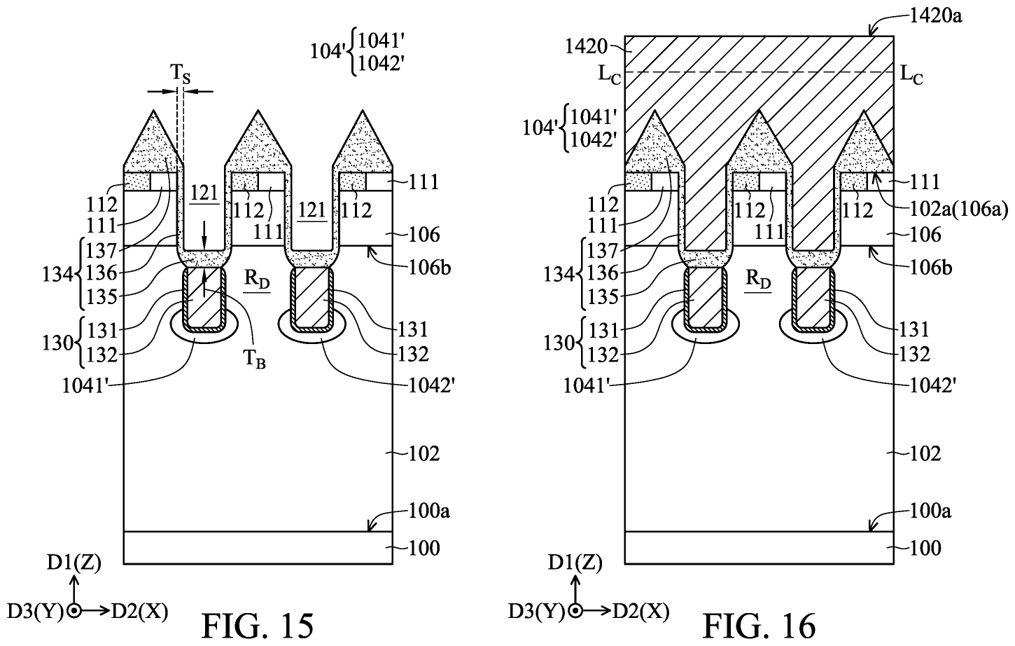

Next, gate structure GS (FIG. 18) are formed on the conductive structures 130. According to some embodiments of the present disclosure, Some intermediate stages of fabricating the gate structure GS are, for example (but not limited to), illustrated in FIG. 15 to FIG. 18.

Referring to FIG. 15, a dielectric layer 134 is formed on at least the lateral surfaces 121s and the bottom surfaces 121b of the first trenches 121, in accordance with some embodiments of the present disclosure. In this exemplified embodiment, a dielectric material is formed on the structure shown in FIG. 14. For example, the dielectric material is formed on the pad oxide layer 114 and the remaining portions of the insulating layer 123, so as to form a dielectric layer 134 as shown in FIG. 15. Specifically, the portions of the dielectric layer 134 that are formed on the conductive structures 130 and positioned in the lower portions of the first trenches 121 are referred to as bottom portions 135 of the dielectric layer 134. The insulating layer 123 and the portions of the dielectric layer 134 that are formed on the remaining portions of the insulating layer 123 in the first trenches 121 are collectively referred to as sidewall portions 136 of the dielectric layer 134. The pad oxide layer 114 and the portions of the dielectric layer 134 that are formed on the pad oxide layer 114 are collectively referred to as top portions 137 of the dielectric layer 134. That is, the dielectric layer 134 includes the bottom portions 135, the sidewall portions 136 and the top portions 137.

In some embodiments, as shown in FIG. 15, the thickness T_{B} of the bottom portions 135 of the dielectric layer 134 is greater than the thickness T_{S} of the sidewall portions 136 of the dielectric layer 134. The thickness T_{B} is, for example, the thickness in the first direction D1 (such as Z direction), and the thickness T_{S} is, for example, the thickness in the second direction D2 (such as Z direction). In some embodiments, the bottom portions 135 of the dielectric layer 134 in the first trenches 121 can electrically isolate the subsequently formed gate electrodes 142′ from the underlying conductive structures 130. Therefore, each of the bottom portions 135 of the dielectric layer 134 that has a sufficient thickness T_{B} provides good electrical isolation between the gate electrode 142′ and the underlying conductive structure 130.

In some embodiments, the insulating layer 123 and the dielectric layer 134 may include the same material or different materials. In some embodiments, the pad oxide layer 114 and the dielectric layer 134 may include the same material or different materials. To simplify the drawings, the pad oxide layer 114 and/or the insulating layer 123 are omitted in FIG. 15 to FIG. 20 for the sake of simplicity and clarity.

In some embodiments, the dielectric layer 134 includes oxide such as silicon oxide, or another suitable dielectric material, or a combination of the aforementioned materials. In some embodiments, the dielectric layer 134 may be a single dielectric layer or include multiple layers of dielectric materials.

In some embodiments, the dielectric layer 134 can be formed on the first heavily doped regions 111, the second heavily doped regions 112, and the lateral surfaces 121s and the bottom surfaces 121b of the first trenches 121 by a deposition process. The aforementioned deposition process is, for example, a conformal deposition process, and may be a chemical vapor deposition (CVD) process, an atomic layer deposition (ALD) process, another suitable deposition process, or a combination of the aforementioned processes.

In this exemplified embodiment, a dielectric material can be deposited by using a high density plasma chemical vapor deposition (HDP CVD) process to form the dielectric layer 134 in FIG. 15. In the HDP chemical vapor deposition process, a deposition rate of the dielectric material in the vertical direction (such as in the first direction D1) is greater than a deposition rate of the dielectric material in the horizontal direction (such as the second direction D2). Therefore, as shown in FIG. 15, the thickness T_{B} of the bottom portions 135 of the dielectric layer 134 is greater than the thickness T_{S} of the sidewall portions 136 of the dielectric layer 134, in accordance with some embodiments of the present disclosure. In addition, as shown in FIG. 15, the top portions 137 of the dielectric layer 134 each have a tapered profile due to the difference in deposition rates in the vertical and horizontal directions. However, it should be noted that dimensions, shapes and formation methods of the dielectric layer 134 in FIG. 15 are provided for illustrative purposes, and the embodiments of the present invention are not limited thereto.

After the portions of the dielectric layer 134 are removed in subsequent process, the remaining portions of the dielectric layer 134 in the respective first trenches 121 can serve as a gate dielectric layer 134′ (FIG. 18) of a gate structure. Details of the fabrication of the gate dielectric layer 134′ will be described below.

Referring to FIG. 16, a second conductive material 1420 is deposited on the top surface 102a of the epitaxial layer 102, in accordance with some embodiments of the present disclosure. Specifically, the second conductive material 1420 is formed on the dielectric layer 134 and fills the first trenches 121. In addition, in some embodiments, if the dielectric layer 134 has an uneven top surface, the second conductive material 1420 can be excessively deposited on the dielectric layer 134 to a specific thickness, so that the top surface 1420a of the second conductive material 1420 that is higher than the topmost portion of the dielectric layer 134 is a flat surface.

In some embodiments, the second conductive material 1420 may include metal, alloy, polysilicon, another suitable conductive material, or a combination of the aforementioned materials. In some embodiments, the second conductive material 1420 can be a single-layer structure or a multilayer structure that includes one of more of the aforementioned materials. In this exemplified embodiment, the second conductive material 1420 is depicted as a single-layer structure for the purpose of simplicity and clarity of the drawings.

In addition, the conductive structures 130 in the second trenches 126 (including the conductive portions 132 made of the first conductive material 1320) are separated from the second conductive material 1420 by the bottom portions 135 of the dielectric layer 134. In some embodiments, the first conductive material 1320 and the second conductive material 1420 include the same conductive material. In some other embodiments, the first conductive material 1320 and the second conductive material 1420 include different conductive materials. In this exemplified embodiment, the first conductive material 1320 and the second conductive material 1420 include polysilicon.

In some exemplified embodiments, the aforementioned deposition process includes a physical vapor deposition (PVD) process, a chemical vapor deposition (CVD) process, another suitable process, or a combination of the aforementioned processes to deposit the second conductive material 1420.

Next, in some embodiments, a portion of the second conductive material 1420 is removed, and the remaining portion of the second conductive material 1420 fills up the first trenches 121 to form the conductive portions 142′ (FIG. 18). The portion of the second conductive material 1420 can be removed by using a planarization process and an etching process to form the conductive portions 142′. Details for forming the conductive portions 142′ will be described below.

In some embodiments, as shown in FIG. 16, an excess portion of the second conductive material 1420 is firstly removed by a planarization process. For example, the portion of the second conductive material 1420 that is above a plane indicated by the line L_{C}-L_{C} is removed first. In this exemplified embodiment, after the planarization process, the remaining portion of the second conductive material 1420 has a flat top surface, as indicated by the line L_{C}-L_{C}. The remaining portion of the second conductive material 1420 still covers the dielectric layer 134 although the flat top surface is close to the top portions of the dielectric layer 134.

The aforementioned planarization process is, for example, a chemical mechanical polishing (CMP) process, a mechanical polishing process, an etching process, another suitable process, or a combination of the aforementioned processes.

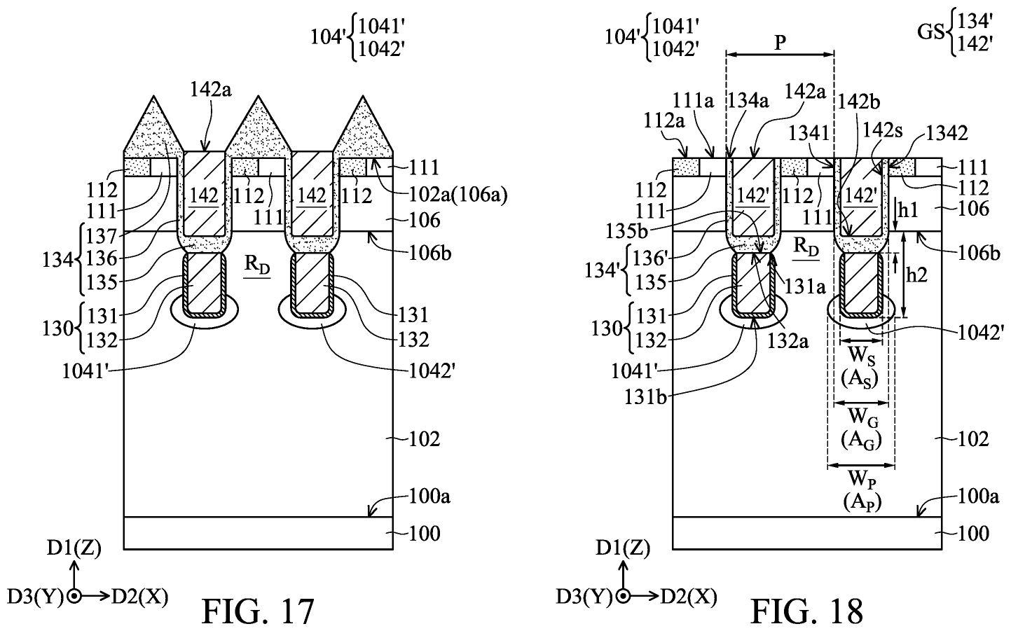

Next, referring to FIG. 17, a portion of the second conductive material 1420 is removed to recess the second conductive material 1420 until the top portions 137 of the dielectric layer 134 are exposed, in accordance with some embodiments of the present disclosure. The remaining portions 142 of the second conductive material 1420 fill the respective first trenches 121, and cover the sidewall portions 136 of the dielectric layer 134 and the top portions 137 of the dielectric layer 134. In this exemplified embodiment, the top surfaces 142a of the remaining portions 142 of the second conductive material 1420 are slightly higher than the top surface 102a of the epitaxial layer 102. In some embodiments, the top surfaces 142a of the remaining portions 142 of the second conductive material 1420 are substantially level with the top surface 102a of the epitaxial layer 102.

In some embodiments, a portion of the second conductive material 1420 can be removed by using a blanket etching process to form the remaining portions 142 of the second conductive material. The blanket etching process is performed without using any photoresist. The second conductive material 1420 is selectively etched along the dielectric layer 134 to remove a portion of the second conductive material 1420 until the remaining portions 142 of the second conductive material reach a specific depth. In one example, the aforementioned blanket etching process is a dry etching process. In this exemplified embodiment, after the blanket etch process is completed, the top surfaces 142a of the remaining portions 142 of the second conductive material 1420 are substantially level with the top surface 102a of the epitaxial layer 102.

Next, referring to FIG. 18, portions of the dielectric layer 143 are removed to expose the first heavily doped regions 111 and the second heavily doped regions 112, in accordance with some embodiments of the present disclosure. The remaining portions of the dielectric layer 143 form the gate dielectric layers 134′ in the respective first trenches 121. In this exemplified embodiment, a gate dielectric layer 134′ in each of the first trenches 121 includes a sidewall portion 136′ and a bottom portion 135.

In some embodiments, the top portions 137 (FIG. 17) and the portions of the sidewall portions 136 of the dielectric layer 134 can be removed by a planarization process. In addition, the remaining portions 142 of the second conductive material 1420 can be planarized through this planarization process. The aforementioned planarization process is, for example, a chemical mechanical polishing (CMP) process, a mechanical polishing process, an etching process, another suitable process, or a combination of the aforementioned processes. In this exemplified embodiment, the dielectric layer 134 (or together with the remaining portions 142 of the second conductive material 1420) can be polished by using a CMP process.

In some embodiments, as shown in FIG. 18, after the aforementioned removal step, the remaining portions of the dielectric layer 143 form a gate dielectric layer 134′ in the respective first trenches 121, and the remaining portions of the second conductive material 1420 form a conductive portion 142′ in the respective first trenches 121. The gate dielectric layer 134′ and the conductive portion 142′ collectively form a gate structure GS. The gate dielectric layer 134′ covers the sidewall 142s and the bottom surface 142b of the conductive portion 142′.

In this exemplified embodiment, adjacent gate structures GS are separated from each other in the second direction D2, and each of the gate structures GS extends in the third direction D3. In addition, a portion (for example, a bottom portion) of the gate structure GS is positioned in the drift region R_{D}. Similarly, the conductive structures 130 that are formed under the gate structures GS are separated from each other in the second direction D2, and each of the conductive structures 130 extends in the third direction D3.

In addition, the top surfaces 134a of the gate dielectric layers 134′ are substantially level with the top surfaces 142a of the conductive portions 142′, in accordance with some embodiments of the present disclosure. In some embodiments, the top surfaces 134a of the gate dielectric layers 134′, the top surfaces 142a of the conductive portions 142′, the top surfaces 111a of the first heavily doped regions 111 and the top surfaces 112a of the second heavily doped regions 112 are substantially coplanar.

In some embodiments, the gate structure GS in each of the first trenches 121 is physically and electrically isolated from the conductive structure 130 in the respective second trench 126 below. For example, the conductive portion 142′ of the gate structure GS is physically and electrically separated from the underlying conductive portion 132 of the conductive structure 130 by the gate dielectric layer 134′ (such as by the bottom portion 135 of the gate dielectric layer 134′). In this exemplified embodiment, as shown in FIG. 18, the conductive portions 132 of the conductive structures 130 (such as the top surface 132a of the conductive portions 132) and the metal silicide liners 131 (such as the top surfaces 131a of the metal silicide liners 131) are in direct contact with the gate dielectric layers 134′ of the gate structures GS.

In addition, opposite sides of a gate structure GS are in contact with respective heavily doped regions of different conductivity types, in accordance with some embodiments of the present disclosure. Specifically, as shown in FIG. 18, one of the first heavily doped regions 111 (such as p-type) is positioned on the first side 1341 of a gate structure GS, and the second heavily doped region 112 (such as n type) is positioned on the second side 1342 of the gate structure GS. The second side 1342 is opposite to the first side 1341. The first heavily doped region 111 is in direct contact with a portion of the gate dielectric layer 134′ that is adjacent to the first side 1341. The second heavily doped region 112 is in direct contact with another portion of the gate dielectric layer 134′ that is adjacent to the second side 1342.

In addition, in the method for forming the conductive structures 130 and the gate structures GS of some embodiments, elongated trenches (each including a first trench 121 that penetrates through the well region 106 and a second trench 126 that extends in the drift region R_{D}) are formed in the epitaxial layer 102. Then, the conductive structures 130 are formed in the second trenches 126, and the gate structures GS are formed in the first trenches 121 that are above the conductive structures 130. Therefore, the conductive structures 130 provided in the embodiments would not additionally occupy the mesa area of the epitaxial layer 102. In some embodiments, there is a first distance h1 in the first direction D1 between the bottom surface of the gate structure GS (i.e., the bottom surface 135b of the bottom portion 135 of the dielectric layer 134) and the bottom surface 106b of the well region 106. There is a second distance h2 in the first direction D1 between the bottom surface of the conductive structure 130 (that is, the bottom surface 131b of the metal silicide liner 131) and the bottom surface 106b of the well region 106. The second distance h2 is greater than the first distance h1.

In addition, when it is viewed from the top of the well region 106, the projection area of the gate structure GS on the substrate 100 overlaps the projection area of the conductive structure 130 on the substrate 100, in accordance with some embodiments of the present disclosure. According to some embodiments, when it is viewed from the top of the well region 106, a projection area of the gate structure GS on the substrate 100 overlaps the projection area of the underlying shielding region 1042′ (or 1041′) on the substrate 100, in accordance with some embodiments of the present disclosure.

Specifically, as shown in FIG. 18, in some embodiments, the width W_{G} of the gate structure GS represents the width of the projection area A_{G} of the gate structure GS on the substrate 100, and the width W_{S} of the conductive structure 130 represents the width of the projection area A_{S} of the conductive structure 130 on the substrate 100. The width W_{G} of the gate structure GS is greater than the width W_{S} of the underlying conductive structure 130, so the projection area A_{G} of the gate structure GS on the substrate 100 covers the projection area A_{S} of the conductive structure 130 on the substrate 100. In addition, in some embodiments, the width W_{P} of the shielding region 1042′ (or the shielding region 1041′) represents the width of its projection area A_{P} on the substrate 100. The width W_{G} of the gate structure GS may be greater than, less than or approximately equal to the width W_{P} of the shielding region 1042′ (or the shielding region 1041′). The shielding region 1042′ (or the shielding region 1041′) covers a part of the bottom portion of the conductive structure 130, and the projection area A_{P} of the shielding region 1042′ (or the shielding region 1041′) overlaps the projection area A_{S} of the gate structure GS.

According to the aforementioned embodiment, the conductive structures 130 are formed under the respective gate structures GS, and the gate structures GS, the first heavily doped regions 111 and the second heavily doped regions 112 are arranged alternately at the top surfaces 102a of the epitaxial layer 102. As shown in FIG. 18, only one first heavily doped region 111 and one second heavily doped region 112 are formed at the top surface 102a of the epitaxial layer 102 are formed between two adjacent gate structures GS, in accordance with some embodiments of the present disclosure. Therefore, the conductive structures 130 of the embodiments can greatly reduce the pitch P of the gate structures GS.

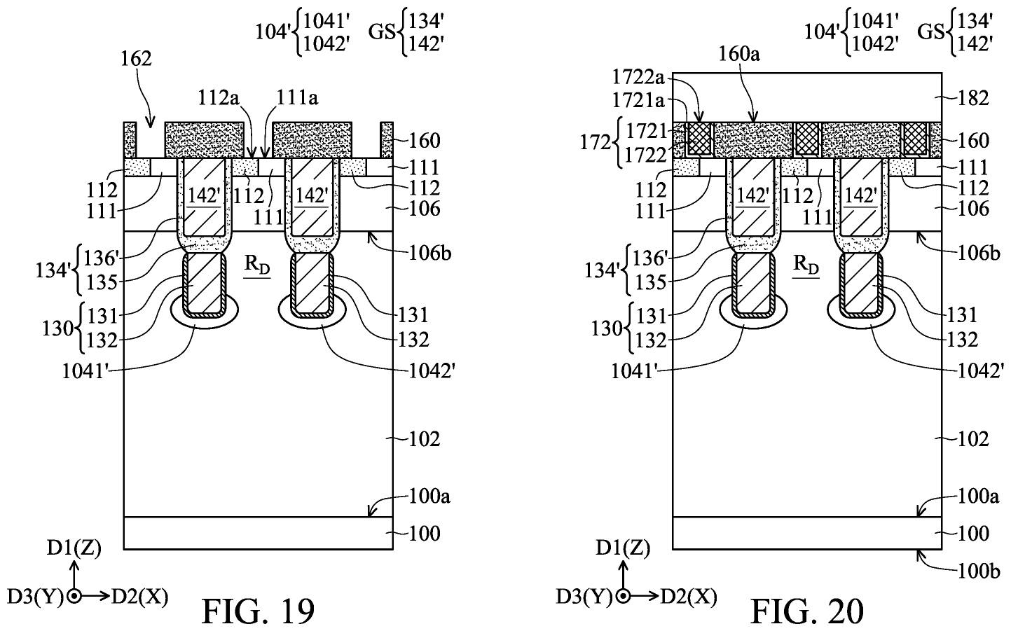

After the epitaxial layer 102, the well region 106, the first heavily doped regions 111, the second heavily doped regions 112, the conductive structures 130 and the gate structures GS are formed as described above, contact plugs 172 are formed (FIG. 20) and electrically connected to the first heavily doped regions 111, the second heavily doped regions 112 and the well region 106. Then, a source metal layer 182 (FIG. 20) and a drain metal layer (not shown) are formed, and the fabrication of a semiconductor device is completed. FIG. 19 and FIG. 20 illustrate cross-sectional views of intermediate stages of a method for forming contact plugs and a source metal layer, in accordance with some embodiments of the present disclosure.

Referring to FIG. 19, an interlayer dielectric (ILD) layer 160 is formed over the epitaxial layer 102, and the interlayer dielectric layer 160 covers the gate structures GS and portions of the first heavily doped regions 111 and portions of the second heavily doped regions 112, in accordance with some embodiments of the present disclosure. In some examples, the interlayer dielectric layer 160 has several contact holes 162. These contact holes 162 are located between two adjacent gate structures GS. Each contact hole 162 exposes a portion of a first heavily doped region 111 and a portion of a second heavily doped region 112. As shown in FIG. 19, each contact hole 162 exposes a portion of the top surface 111a of the first heavily doped region 111 and a portion of the top surface 112a of the second heavily doped region 112, in accordance with some embodiments of the present disclosure.

In some embodiments, the interlayer dielectric layer 160 includes silicon oxide, or another suitable dielectric material, or a combination of the aforementioned materials. In some embodiments, the material of the interlayer dielectric layer 160 is different from the material of the gate dielectric layer 134′. In some other embodiments, the material of the interlayer dielectric layer 160 is the same as the material of the gate dielectric layer 134′.

According to some embodiments, the interlayer dielectric layer 160 that has several contact holes 162 can be formed by a deposition process, a lithographic patterning process and an etching process. In this exemplified embodiment, an interlayer dielectric material (not shown) is firstly deposited on the first heavily doped regions 111, the second heavily doped regions 112 and the gate structures GS by a deposition process. Then, a lithography patterning process is performed to remove portions of the interlayer dielectric material, so as to form the contact holes 162.

In some embodiments, the aforementioned deposition process can be a chemical vapor deposition process, another suitable process, or a combination of the foregoing processes. In some embodiments, the aforementioned lithographic patterning process includes photoresist coating (e.g., spin-on coating), soft baking, mask alignment, exposure, post-exposure baking, developing the photoresist, rinsing and drying (e.g., hard baking), another suitable process or a combination of the foregoing processes. In some embodiments, the aforementioned etching process includes a dry etching process, a wet etching process, a plasma etching process, a reactive ion etching process, another suitable process, or a combination of the foregoing processes.

Next, referring to FIG. 20, contact plugs 172 are formed in the respective contact holes 162, in accordance with some embodiments of the present disclosure. The contact plugs 172 are formed on the epitaxial layer 102 and in direct contact with the respective first heavily doped regions 111 and the respective second heavily doped regions 112.

In some embodiments, the second heavily doped regions 112 that have the first conductivity type (such as n-type) serve as source regions of the semiconductor device. The first heavily doped regions 111 that have the second conductivity type (such as p-type) are in direct contact with the underlying well region 106. Accordingly, the contact plugs 172 have good ohmic contacts with the well region 106 through the first heavily doped regions 111.

In some embodiments, each of the contact plugs 172 includes a contact barrier layer 1721 and a contact conductive layer 1722. The contact barrier layer 1721 is formed on the sidewall and bottom of the contact hole 162 (FIG. 19), and can be referred to as a barrier liner. The contact conductive layer 1722 fills the remaining space in the contact hole 162. In this exemplified embodiment, as shown in FIG. 20, the top surface 1721a of the contact barrier layer 1721 and the top surface 1722a of the contact conductive layer 1722 are coplanar with the top surface 160a of the interlayer dielectric layer 160.

In some exemplified embodiments, a barrier material (not shown) can be formed on the interlayer dielectric layer 160 by using a deposition process. The barrier material is conformably deposited in the contact holes 162 (FIG. 19). Then, a conductive material (not shown) is deposited on the barrier material layer, and the conductive material fills the remaining space in the contact holes 162. Next, excess portions of the conductive material and barrier material that are formed above the interlayer dielectric layer 160 are removed (for example, by using an etching process) to form the contact barrier layers 1721 and the contact conductive layers 1722 in the respective contact holes 162.

In some embodiments, the contact barrier layers 1721 may include titanium (Ti), titanium nitride (TiN), tantalum (Ta), tantalum nitride (TaN), cobalt (Co), another suitable barrier material, or a combination of the aforementioned materials. In some embodiments, the contact barrier layers 1721 can be formed by a chemical vapor deposition (CVD) process, an atomic layer deposition (ALD) process, a physical vapor deposition (PVD) process, another suitable process, or a combination of the foregoing processes.

In some embodiments, the contact conductive layers 1722 can be a single-layer structure or a multilayer structure. The contact conductive layers 1722 may include tungsten (W), aluminum (Al), copper (Cu), titanium (Ti), tantalum (Ta), Titanium nitride (TiN), tantalum nitride (TaN), nickel silicide (NiSi), cobalt silicide (CoSi), another suitable metal, or a combination of the aforementioned materials. In addition, in some embodiments, the aforementioned conductive material can be formed by using a chemical vapor deposition process, an atomic layer deposition process, a physical vapor deposition process, another suitable process, or a combination of the aforementioned processes.

According to some embodiments of the present disclosure, the first heavily doped regions 111 (such as p+ regions) and the second heavily doped regions 112 (such as n+ regions) that correspond to each of the contact plugs 172 are electrically connected to each other. If there is electric charge accumulation (making the voltage not zero) between the source regions (i.e., the second heavily doped regions 112) and the body region (i.e., the well region 106), it will affect the threshold voltage of the semiconductor device, for example, leading to an unstable threshold voltage. This is known as a body effect. However, according to some embodiments of the present disclosure, since the second heavily doped regions 112 (i.e., the source region) are grounded, and the first heavily doped regions 111 and the second heavily doped regions 112 are in physical contact and electrical connected to each other. When the semiconductor device is operated, the electric charges accumulated at the well region 106 can flow to the grounded second heavily doped regions 112 by passing through the first heavily doped regions 111 to be eliminated, in accordance with some embodiments of the present disclosure. Therefore, the aforementioned body effect can be prevented, and the semiconductor device has a stable threshold voltage.

Referring to FIG. 20 again, in some embodiments, after the contact plugs 172 are formed, a metal layer 182 is formed over the interlayer dielectric layer 160 and the contact plugs 172. The metal layer 182 covers the contact plugs 172 and is in physical and electrical contact with the contact plugs 172. Therefore, the metal layer 182 is electrically connected to the first heavily doped regions 111, the second heavily doped regions 112 and the well region 106 through the contact plugs 172.

The metal layer 182 can be used as a top metal of a semiconductor device, in accordance with some embodiments of the present disclosure. The metal layer 182 is electrically connected to the second heavily doped regions 112 that serve as the source regions. Thus, the metal layer 182 is also called a source metal layer (source metal layer) 182. In some embodiments, the conductive structures 130 are electrically connected to the source metal layer 182 via other interconnections (not shown).

In some embodiments, the metal layer 182 includes copper, silver, gold, aluminum, tungsten, another suitable metal material, or a combination of the aforementioned materials. In some embodiments, the material of the metal layer 182 is the same as the material of the contact plugs 172. In some other embodiments, the material of the metal layer 182 is different from the material of the contact plugs 172. According to some embodiments, the metal layer 182 may be formed on the contact plug 172 by using a deposition process. In some embodiments, the deposition process may include a physical vapor deposition process, a chemical vapor deposition process, another suitable process, or a combination of the aforementioned processes.

In addition, the substrate 100 that has the first conductivity type can be used as a drain region of a semiconductor device, in accordance with some embodiments of the present disclosure. Besides the aforementioned source metal layer 182, a semiconductor device further includes a drain metal layer (not shown) on the backside of the substrate 100 with the first conductivity type (such as n-type) to complete the manufacturing process of a semiconductor device. In some exemplified embodiments, the thickness of a wafer can be thinned by using a backside grounding process, and then a backside metal is formed on the backside of the wafer, for example, on the bottom surface 100b of the substrate 100, to form the drain metal layer.

According to the aforementioned descriptions, semiconductor devices and methods for forming the same, in accordance with some embodiments of the present disclosure, have many advantages. In some embodiments, the conductive structures 130 of the semiconductor device can be electrically connected to the source metal layer 182 via other interconnections (not shown). When the operation of the semiconductor device of the embodiment is performed, the second heavily doped regions 112 (i.e., the source regions) and the source metal layer 182 are grounded. The drift region R_{D} (having the second conductivity type, such as n-type) and the conductive structure 130 that is electrically connected to the source form a Schottky diode. In some embodiments, the body diode that is generated at the interface of the well region 106 (having the first conductivity type, such as p-type) and the drift region R_{D} is connected in parallel with the Schottky diode. When the semiconductor device of the embodiments is operated, the electric carriers flow through the Schottky diode that has a lower on-resistance (Von) instead of through the body diode. Therefore, in some embodiments, the conductive structure 130 that is electrically connected to the source (including the source metal layer 182 and the source region (i.e., the second heavily doped regions 112)) and the drift region R_{D} form a Schottky diode. The Schottky diode disables the function of the body diode and decreases the on-resistance, thereby reducing the power loss of the semiconductor device.

In addition, the conductive structures 130 as parts of the aforementioned Schottky diodes are formed under the respective gate structures GS, for example, formed in the drift region R_{D}, in accordance with some embodiments of the present disclosure, thereby reducing the gate-drain capacitance (Cgd). In addition, no extra mesa area of the epitaxial layer is required for disposing the conductive structures, so the cell pitch between adjacent components (for example, the cell pitch between two adjacent gate structures) in the semiconductor devices can be reduced, thereby decreasing the resistance of the channel regions and reducing the lateral dimension of the epitaxial layer. In some embodiments, only one first heavily doped region 111 and one second heavily doped region 112 are included between two adjacent gate structures GS (FIG. 20), so the distance between adjacent gate structures GS can be greatly reduced, thereby reducing the lateral dimension of the epitaxial layer and the area of the semiconductor device.

In addition, according to some embodiments, the method for forming the conductive structures 130 and the gate structures GS includes that continuous trenches are formed in the epitaxial layer 102. For example, the first trenches 121 are formed to penetrates the well region 106 and extended to the drift region R_{D} to form the second trenches 126 under the respective first trenches 121. Then, the conductive structures 130 are formed in the second trenches 126 and the gate structures GS are formed in the first trenches 121. Therefore, according to the method for forming a semiconductor device provided in the embodiments, the formation positions of the conductive structures 130 and the gate structures GS can be controlled through the extension direction of the trenches in the epitaxial layer 102, so that the conductive structure 130 and the gate structure GS can be precisely aligned to each other. Thus, according to the aforementioned descriptions, the conductive structures 130 of the semiconductor device in the embodiments can be precisely aligned to the gate structures GS by using the method of the embodiments that is compatible with the existing manufacturing processes. In addition, the semiconductor device that is formed by the method of the embodiments includes Schottky diodes to decrease the on-resistance and reduce the power loss, while the cell pitch between adjacent components (such as adjacent gate structures GS) in the semiconductor device can also be reduced. In addition, the area of the semiconductor device that is formed by the method of the embodiments can be reduced.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate having a first conductivity type;
an epitaxial layer on the substrate, wherein the epitaxial layer has the first conductivity type;
a well region over the substrate, wherein the well region extends downward from a top surface of the epitaxial layer into the epitaxial layer, and the well region has a second conductivity type;
a drift region formed in the epitaxial layer and in contact with a bottom surface of the well region, wherein the drift region has the first conductivity type;
a gate structure extending downward from the top surface of the epitaxial layer to penetrate the well region, wherein the gate structure is in contact with the drift region; and
a conductive structure formed in the drift region and under the gate structure,
wherein a gate electrode of the gate structure is separated from the conductive structure by a gate dielectric layer of the gate structure.

2. The semiconductor device as claimed in claim 1, wherein a top surface of the conductive structure is lower than the bottom surface of the well region.

3. The semiconductor device as claimed in claim 1, wherein a bottom surface of the gate structure is separated from the bottom surface of the well region by a first distance, and a bottom surface of the conductive structure is separated from the bottom surface of the well region by a second distance,
wherein the second distance is greater than the first distance.

4. The semiconductor device as claimed in claim 1, wherein a width of the gate structure is greater than a width of the conductive structure.

5. The semiconductor device as claimed in claim 1, wherein a projection area of the gate structure on the substrate overlaps a projection area of the conductive structure on the substrate as viewed from a top side of the well region.

6. The semiconductor device as claimed in claim 1, wherein the gate dielectric layer includes a bottom portion and a sidewall portion, and a thickness of the bottom portion is greater than a thickness of the sidewall portion,
wherein the conductive structure is electrically insulated from the gate electrode by the bottom portion of the gate dielectric layer.

7. The semiconductor device as claimed in claim 1, further comprising a shielding region formed in the epitaxial layer, wherein the shielding region covers a bottom surface and a portion of lateral surfaces of the conductive structure, and the shielding region has the second conductivity type; and
wherein a projection area of the gate structure on the substrate overlaps a projection area of the shielding region on the substrate as viewed from a top side of the well region.

8. The semiconductor device as claimed in claim 1, wherein the conductive structure comprises a conductive portion and a metal silicide liner that covers sidewalls and a bottom surface of the conductive portion.

9. The semiconductor device as claimed in claim 8, wherein the conductive portion and the metal silicide liner are in contact with the gate dielectric layer of the gate structure.

10. The semiconductor device as claimed in claim 1, further comprising:
a first heavily doped region formed in the well region and positioned on a first side of the gate structure, wherein the first heavily doped region has the second conductivity type; and
a second heavily doped region formed in the well region and positioned on a second side of the gate structure, wherein the second side is opposite to the first side of the gate structure, the second heavily doped region has the first conductivity type, and the first conductivity type is different from the second conductivity type.

11. The semiconductor device as claimed in claim 10, wherein the first heavily doped region is in direct contact with a portion of the gate dielectric layer that is adjacent to the first side of the gate structure; and
wherein the second heavily doped region is in direct contact with another portion of the gate dielectric layer that is adjacent to the second side of the gate structure.

12. The semiconductor device as claimed in claim 11, wherein a top surface of the conductive structure is lower than a bottom surface of the first heavily doped region, and the top surface of the conductive structure is lower than a bottom surface of the second heavily doped region.

13. The semiconductor device as claimed in claim 11, further comprising:
another first heavily doped region formed in the well region, wherein the other first heavily doped region is positioned adjacent to the second heavily doped region and in direct contact with the second heavily doped region, and
wherein the second heavily doped region is positioned between the other first heavily doped region and the gate structure.

14. The semiconductor device as claimed in claim 13, further comprising:
another gate structure adjacent to the gate structure and extending downward from the top surface of the epitaxial layer to penetrate the well region, wherein the other gate structure is in contact with the drift region, and
wherein the other first heavily doped region is positioned between the other gate structure, and the other first heavily doped region is in direct contact with the other gate structure.

15. A method for forming a semiconductor device, comprising:
providing a substrate having a first conductivity type;
forming an epitaxial layer on the substrate, wherein the epitaxial layer has the first conductivity type;
implanting a top surface of the epitaxial layer to form a well region in the epitaxial layer, wherein the well region has a second conductivity type, a drift region of the first conductivity type is formed below the well region, and the drift region is in contact with a bottom surface of the well region;
forming conductive structures in the drift region; and
forming gate structures over the respective conductive structures, wherein the gate structures extend downward from the top surface of the epitaxial layer to penetrate through the well region, bottom portions of the gate structures are positioned in the drift region, and the gate structures each include a gate electrode and a gate dielectric layer that covers the gate electrode,
wherein the conductive structures are separated from the respective gate structures by the respective gate dielectric layers.

16. The method for forming a semiconductor device as claimed in claim 15, wherein after the well region is formed and before the conductive structures are formed, the method further comprises:
implanting the top surface of the epitaxial layer to form first heavily doped portions and second heavily doped portions alternately arranged in the well region, wherein the first heavily doped portions have the second conductivity type and the second heavily doped portions have the first conductivity type; and
removing a portion of each of the first heavily doped portions, a portion of each of the second heavily doped portions, a portion of the well region and a portion of the epitaxial layer to form first trenches,
wherein the first trenches extend downward from the top surface of the epitaxial layer to penetrate through the well region, and bottom surfaces of the first 12 trenches expose the drift region.

17. The method for forming a semiconductor device as claimed in claim 16 wherein the drift region includes shielding regions that are positioned under the respective first trenches, and the shielding regions have the second conductivity type.

18. The method for forming a semiconductor device as claimed in claim 17, further comprising:
removing portions of the drift region and portions of the shielding regions from the bottom surfaces of the first trenches to form second trenches,
wherein the second trenches connect the respective first trenches, and bottom surfaces of the second trenches expose the respective shielding regions.

19. The method for forming a semiconductor device as claimed in claim 18, wherein a width of each of the first trenches is greater than a width of each of the second trenches.

20. The method for forming a semiconductor device as claimed in claim 18, wherein forming the conductive structures comprises:
forming a metal silicide liner in each of the second trenches;
depositing a first conductive material over the top surface of the epitaxial layer, wherein the first conductive material fills the second trenches and the first trenches; and
removing a portion of the first conductive material, wherein remaining portions of the first conductive material in the second trenches are referred to as first 8 conductive portions,
wherein the metal silicide liner in each of the second trenches covers sidewalls and a bottom surface of the first conductive portion.

21. The method for forming a semiconductor device as claimed in claim 20, wherein forming the gate structures comprises:
forming a dielectric layer on sidewalls and bottom surfaces of the first trenches;
depositing a second conductive material over the top surface of the epitaxial layer, wherein the second conductive material is deposited on the dielectric layer, and the first trenches are filled with the second conductive material; and
removing a portion of the second conductive material and a portion of the dielectric layer,
wherein a remaining portion of the second conductive material in each of the first trenches is referred to as a second conductive portion, and a remaining portion of the electrical layer in each of the first trenches is referred to as the gate dielectric layer; and
wherein the gate dielectric layer covers sidewalls and a bottom surface of the second conductive portion in each of the first trenches, and the second conductive 15 portion is separated from the first conductive portion underneath by the gate dielectric layer.

22. The method for forming a semiconductor device according to claim 16, wherein remaining portions of the first heavily doped portions are referred to as first heavily doped regions, and the remaining portions of the second heavily doped portions are referred to as second heavily doped regions,
wherein opposite sides of each of the first trenches are respectively in contact with one of the first heavily doped regions and one of the second heavily doped regions.

23. The method for forming a semiconductor device according to claim 15, further comprising:
forming first heavily doped regions in the well region, wherein the first heavily doped regions are arranged separately from each other, and the first heavily doped regions have the second conductivity type; and
forming second heavily doped regions in the well region, wherein the second heavily doped regions are arranged separately from each other, and the second heavily doped regions have the first conductivity type,
wherein the first conductivity type is different from the second conductivity type.

24. The method for forming a semiconductor device according to claim 23, wherein one of the first heavily doped regions and one of the second heavily doped regions are positioned between two adjacent gate structures.
